(19) United States
(12) Patent Application Publication
(10) Pub. No.: US 2005/0053109 A1
(43) Pub. Date: Mar. 10, 2005

(54) Integrated multiple wavelength system

(76) Inventor: Josh Hogan, Los Altos, CA (US)

Correspondence Address: DEBORAH NEVILLE, PO BOX 61063, PALO ALTO, CA, 94306, US

(21) Appl. No.: 10/449,291

(22) Filed: May 30, 2003

Related U.S. Application Data
(60) Provisional application No. 60/386,052, filed on Jun. 3, 2002.

(51) Int. Cl. H01S 5/00

(52) U.S. Cl. 372/50; 372/23

(57) ABSTRACT

An array of multiple laser diodes, each lasing at different wavelengths, the outputs of which laser diodes are combined in an integrated manner, such that all the generated wavelengths are output to a fiber using a single fiber interconnect. The laser diodes are independently modulated by modulating the electrical current of each laser diode. The outputs of the laser diodes are combined by means of waveguides, which may be on the same substrate. The combined multiple wavelength output may be isolated from disruptive optical feedback by means of a single optical isolator.

### RELATED APPLICATIONS

This application claims priority from co-pending U.S. Provisional Application Ser. No. 60/386,052 filed Jun. 3, 2002.

### FIELD OF INVENTION

The invention relates to wave-length division multiplexing and in particular to an integrated multiple wavelength system

### BACKGROUND OF THE INVENTION

Typically laser diodes are fabricated by dicing a wafer into chips which then have reflective coatings applied to one or both ends. Laser diodes fabricated from the same wafer typically lase at approximately the same wavelength, with some variations or “spread” or deviations in the actual wavelength depending on the physical location on the wafer from which they came.

The diodes can be temperature tuned over a small wavelength range. In DWDM (dense wavelength division multiplexing) optical communications applications, a set of laser diodes diode are required to lase at a set of very specific wavelengths corresponding to the ITU grid. FIG. 1 illustrates the spectrum of a subset of typical wavelengths on the ITU grid. Their center wavelengths are all separated by a fixed frequency difference, DWD, which is accurately 100 GHz or a multiple or sub multiple of 100 GHz. The tolerance on deviation from this center wavelength, dWD, is typically +/−2 GHz, which requires accurate fabrication processes. Such specificity in lasing frequency is typically accomplished by a combination of temperature stabilization and a designed in grating for wavelength locking. This is referred to as a DFB (distributed feedback) laser.

Wafer design thus in large part predetermines the wavelength selection possibilities. Current methodologies enable the designing of wafers such that the wafer will contain laser diodes that by design will lase at significantly different wavelengths. One such enabling technology is known as quantum well intermixing (QWI), which allows the properties of a semiconductor quantum well structure to be modified, typically by modifying the energy bandgap. Such techniques are described in U.S. Pat. No. 6,027,989 titled Bandgap tuning of semiconductor well structure by Poole, et al.

As a result of such techniques, it is possible to produce a wafer containing diodes that lase at different wavelengths. However, such diodes still require tuning and wavelength stabilization after fabrication to achieve the accuracy in wavelength required for DWDM applications. Thus, the necessity for post fabrication tuning and wavelength stabilization precludes fabrication of an array of laser diodes on a single wafer such that each laser diode emits a wavelength corresponding to adjacent grid values (sequential frequencies, separated by 0.8 nm or 100 GigaHertz).

Thus with current fabrication techniques it is not possible to fabricate diodes on a single wafer that lase with sufficient accuracy at the wavelengths of the ITU grid. Diodes must be selected after post fabrication tuning and assembled, each diode having its own connecting fiber.

In addition to DWDM, there is CWDM (coarse wavelength division multiplexing). In CWDM, the wavelength difference between adjacent wavelengths is large, and there is a large tolerance for wavelength inaccuracy in the diodes. For example, FIG. 2 illustrates the spectrum of a subset of typical CWDM wavelengths. Their center wavelengths are all separated by a fixed wavelength difference, DWC which is typically 20 nm (˜2500 GHz). The tolerance on deviation from this center wavelength, dWC, is typically +/−5 nm (625 GHz), which allows relaxed tolerance on the fabrication processes. For example, four CWDM wavelengths at 1510, 1530, 1550, 1570 nm+/−5 nm have a spacing of 20 nm. Consequently, spectrum is not used efficiently, but CWDM does permit the use of inexpensive and unstabilized diodes for optical communications, which allows some reduction in costs.

Still, the requirement of a separate interconnect for each and every diode requires costly alignment and fabrication techniques, has yield, robustness and reliability issues and therefore limits the extent to which costs can be reduced.

There is therefore an unmet need for an array of multiple laser diodes, each lasing at different wavelengths, whose outputs are combined in an integrated manner, such all the generated wavelengths are output to a fiber using a single fiber interconnection.

### SUMMARY OF THE INVENTION

The invention provides an array of multiple laser diodes, each lasing at different wavelengths, the outputs of which laser diodes are combined in an integrated manor, such that all the generated wavelengths are output to a fiber using a single fiber interconnect. The laser diodes may each be independently modulated by modulating the electrical current of each laser diode by means of RF (radio frequency) drivers, which may be on the same substrate. The outputs of the laser diodes may be combined by means of waveguides, which may be on the same substrate. The combined multiple wavelength output may be isolated from disruptive optical feedback by means of a single optical isolator.

### BRIEF DESCRIPTION OF THE DRAWINGS

FIG. 1 is an illustration of DWDM.

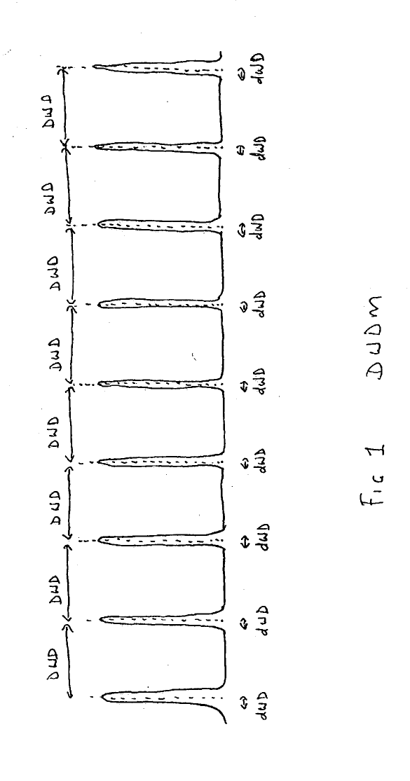

FIG. 2 is an illustration of CWDM.

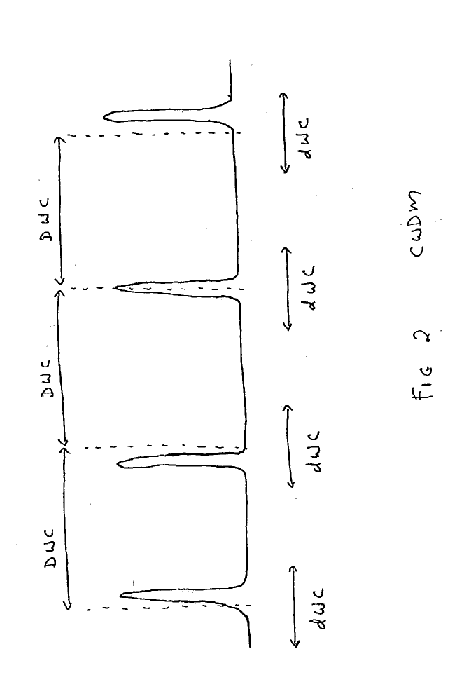

FIG. 3 is a schematic of an integrated multiple wavelength system according to the invention.

### DESCRIPTION OF THE INVENTION

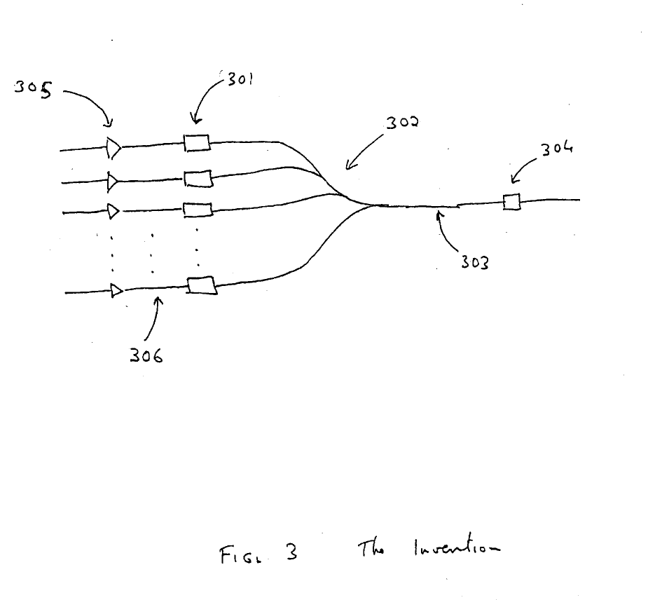

The invention is illustrated in FIG. 3 and provides a combination for CWDM applications such that an array of N laser diodes, 301, lasing at N different wavelengths can be used and fabricated on a single wafer in conjunction with a waveguide-based combiner, 302, which outputs all the wavelengths at a single point, 303, thus requiring only one interconnect for the array. Because the application is CWDM, which has reduced wavelength accuracy requirements, the N wavelengths can be fabricated as an array on a single wafer. The nominal wavelength of each laser diode in the array may be determined by techniques such as quantum well intermixing (QWI), which allows the properties of a semiconductor quantum well structure to be modified, typically by modifying the energy bandgap. This modification may be accomplished by the design of masks used in the fabrication process. The array may be temperature tuned to optimally center the wavelength set on the desired wavelength ranges, without the need to individually wavelength tune each laser diode.

The invention provides for integrated fabrication and a single optical output so that only one optical isolator, 304, and one optical alignment is necessary.

The invention provides for fabrication of a product by directly modulating each of N individual laser diode electronically, with a set of N electronic modulated drivers, 305, permitting a highly integrated solution. This is also a robust solution as only one optical interconnection is required for N electronic interconnections, 306.

1. A method of generating multiple wavelengths and combining them in an integrated manner, the method comprising:
fabricating an array of laser diodes on the same substrate;
determining the nominal wavelength at which each laser diode of the array lases; and
combining the outputs of the laser diodes, such that all wavelengths are output on a single waveguide.

2. The method of claim 1, wherein the nominal wavelength of each laser diode is determined by quantum well intermixing on each laser diode.

3. The method of claim 1, wherein the nominal wavelength of each laser diode is determined by the mask geometry of each laser diode.

4. The method of claim 1, wherein the outputs of the laser diodes are combined by means of waveguides.

5. The method of claim 4, wherein the waveguides are on the same substrate as the laser diodes.

6. The method of claim 1, wherein the determined nominal wavelengths of the array of laser diodes correspond to a set of wavelengths on a Coarse Wavelength Division Multiplex standard.

7. The method of claim 1, wherein the determined nominal wavelengths of the array of laser diodes are centered on the set of wavelengths on a Coarse Wavelength; Division Multiplex standard by means of temperature control of the set of laser diodes.

8. A system for generating multiple modulated wavelengths and combining them in an integrated manner, the method comprising:
fabricating an array of laser diodes on the same substrate; and determining the nominal wavelength at which each laser diode of the array lases;
modulating each laser diode;
combining the outputs of the laser diodes; and
including an optical isolator at the combined output, such that all the modulated wavelengths are output on a single waveguide and isolated from optical feedback.

9. The system of claim 8, wherein each laser diode is modulated by modulating the electrical current to each laser diode.

10. The system of claim 9, wherein the electrical current of each laser diode is modulated by a RF driver on the same substrate.
